(19) United States
(12) Patent Application Publication
(10) Pub. No.: US 2006/0150910 A1
(43) Pub. Date: Jul. 13, 2006

(54) Alignment system, vertical tray transporting assembly, and deposition apparatus with the same

(76) Inventors: Sang-Jin Han, Suwon (KR); Kwan-Seop Song, Suwon (KR); Seok-Heon Jeong, Yongin (KR); Hee-Cheol Kang, Suwon (KR)

Correspondence Address: Robert E. Bushnell, 1522 K Street, N.W., Suite 300, Washington, DC, 20005, US

(21) Appl. No.: 11/302,522

(22) Filed: Dec. 14, 2005

(30) Foreign Application Priority Data
Dec. 16, 2004 (KR) 10-2004-107131
Jan. 5, 2005 (KR) 10-2005-00945
Jan. 5, 2005 (KR) 10-2005-00955

(51) Int. Cl. C23C 16/00

(52) U.S. Cl. 118/721; 118/726; 118/728

(57) ABSTRACT

An alignment system, a vertical tray transporting assembly and a deposition apparatus having the same allow alignment of high precision, and perform a stable deposition process in a short period of time, minimize the effect of fine particles during transportation, and secure a sufficient uniformity of a mask by fixing and supporting a vertically disposed substrate using a fixing holder member and an auxiliary attaching member in a tray of a vertical in-line deposition alignment system.

### CLAIM OF PRIORITY

This application makes reference to, incorporates the same herein, and claims all benefits accruing under 35 U.S.C. §119 from three applications, entitled ALIGNMENT SYSTEM, VERTICAL TRAY TRANSPORTING ASSEMBLY, AND DEPOSITION APPARATUS WITH THE SAME, one of which was earlier filed in the Korean Intellectual Property Office on the 16^{th} of Dec. 2004 and there duly assigned Serial No. 10-2004-0107131, and two of which were concurrently filed on the 5^{th} of Jan. 2005 and there respectively assigned Serial Nos. 10-2005-00945 and 10-2005-00955.

### BACKGROUND OF THE INVENTION

1. Technical Field

The present invention relates to an alignment system, a vertical tray transporting assembly, and a deposition apparatus with the same. The present invention more particularly relates to an alignment system, a vertical tray transporting assembly, and a deposition apparatus with the same, in which a substrate is fixed and supported to embody a vertical deposition in an in-line thin film deposition system, the effect of fine particles during transportation is minimized, and sufficient flatness of a mask is secured.

2. Related Art

Generally, a deposition process of a thin film is divided into a method of depositing a thin film under a vacuum and under atmospheric pressure. Since the method of depositing a thin film under vacuum may form a high purity of a thin film without contamination by impurities, and deposit more dense thin film, it has widely been used for semiconductor and display devices.

Due to a limit of volume of a process chamber and an area of a substrate able to be inserted in the process chamber, a thin film deposition process under a vacuum has been performed in a batch type manner.

There are serious problems in a vertical deposition method, which is one of the methods used for vacuum deposition of a substrate having a large area. In particular, upon vertically disposing the substrate, the problems are worse due to the effect of gravity acting downward. Furthermore, in an in-line deposition system, problems such as deterioration of the yield of the product due to the delay in processing occur.

In addition, there is an EL device which is an example in representative application fields of a deposition apparatus. The EL device is an emissive display having a wide angle of visibility, excellent contrast, and a high-speed response, and has been proposed as the next-generation planar type display device. The EL device is divided into an organic EL device and an inorganic EL device according to the kind of emission layer formation materials. The organic EL device has more excellent luminance, drive voltage, and response speed characteristics in comparison with the inorganic EL device, and has a polychromatic characteristic.

The organic EL device includes an anode electrode and a cathode electrode arranged to face each other, and an organic layer sandwiched between the anode and cathode electrodes. The organic layer includes a hole transfer layer (HIL), an electron transfer layer (ETL), and an electron transfer layer (ETL). In the organic EL device, when a predetermined voltage is applied to the anode and cathode electrodes, holes from the hole transfer layer (HIL) and electrons from the electron transfer layer (ETL) and are transported to an emission layer (EML), and the holes and electrons are recombined with each other in the emission layer (EML), whereby predetermined light is emitted.

A thin film, such as an organic film of an organic EL device, is deposited using a general deposition method. In the general deposition method, after a substrate is disposed in a deposition chamber, organic materials are discharged from a deposition source to deposit a thin film on the substrate. Methods such as the bottom-up rotation deposition type, bottom-up deposition type, top-down deposition type, and vertical deposition type have been variously attempted for depositing organic thin film of the organic EL device. The bottom-up rotation deposition type is a method which deposits a thin film by rotating a substrate against a deposition source. However, it is difficult to apply the bottom-up rotation deposition type method to a substrate having a large area. The bottom-up deposition type is a method which deposits a thin film by horizontal movement of a substrate or a deposition source after the deposition source is disposed at a lower portion of the substrate. In the bottom-up deposition type, a deflection of the substrate or the mask occurs. Accordingly, it is difficult to deposit a precise pattern. Furthermore, uniform thickness of a formation film can be obtained. Moreover, a top-down deposition type injects organic materials downward by horizontally moving a substrate to deposit a thin film. Although deposition materials have high deposition efficiency, it is possible to directly expose a surface of the thin film to be deposited to fine particles.

The vertical deposition type is a method which deposits a thin film by moving a substrate or by moving a deposition source up and down after vertically making the substrate stand. When the vertical deposition type is used, it has been required that a substrate having a large area be easily transported, precision alignment for a precision patterning be easily adjusted, and bending due to enlargement of the substrate be minimized.

### SUMMARY OF THE INVENTION

Accordingly, it is an aspect of the present invention to provide an alignment system, a vertical tray transporting assembly, and a deposition apparatus with the same which allow an alignment of high precision, and perform a stable deposition process in a short period of time, which minimize the effect of fine particles during transportation, and which secure a sufficient uniformity of a mask by fixing and supporting a vertically disposed substrate using a fixing holder member and an auxiliary attaching member in a tray of a vertical in-line deposition alignment system.

The foregoing and/or other aspects of the present invention are achieved by providing an alignment system comprising: a substrate vertically installed and to which a substrate is stuck; a mask tray vertically aligned in correspondence to the substrate tray and to which a mask is stuck; and a tray holder. The substrate tray and the mast tray being locked to the tray holder by means of a locking portion.

The locking portion includes locking holes respectively formed at the substrate tray and the mask tray, and a locking arm formed at the tray holder, and inserted and locked in the locking holes. The locking arm includes a locking groove, and a part of an edge of the locking hole of the mask tray is inserted in the locking groove. Preferably, the locking hole of the mask tray is formed by two holes having different diameters overlapping each other, and the locking hole of the mask tray has holes of smaller and larger diameters overlapping each other to prevent interference due to movement of the locking arm in such a manner that the hole of smaller diameter is positioned at an upper portion of the hole of larger diameter. Most preferably, the mast tray further includes a support member formed so as to protrude from an opposite side of an insertion direction of the locking arm, a part of the support member contacting a head end of the locking arm.

Also, the tray holder includes a holder plate driven by a driver and arranged in the vicinity of the substrate tray. The alignment system further comprises an auxiliary locking portion for maintaining locking positions of the mask tray and the substrate tray locked to the tray holder. In the embodiment, the auxiliary locking portion includes a magnetic substance for sequentially providing a mutual attractive force to the substrate tray the mask tray, and the tray holder. In addition, a magnetic substance of the tray holder is installed at a holder plate.

Furthermore, the substrate tray includes at least one fixing holder member. Preferably, the tray holder includes: a flat plate chuck for pressurizing the substrate; a driver connected to the flat plate chuck for moving the flat plate chuck; and a fixing insertion member engaged with a fixing holder member. The fixing holder member includes a through hole having circular shapes of two different diameters overlapping each other, and the through hole includes a through hole of smaller diameter and a through hole of larger diameter, the through hole of smaller being positioned at an upper portion of the through hole of larger diameter. The fixing insertion member is inserted in the fixing holder member, and locks and fixes the tray, and a groove is formed at the fixing insertion member. The groove of the fixing insertion member is inserted and mounted in the fixing holder member. Also, at least one auxiliary attaching member is formed at the tray and an auxiliary support member is formed at the alignment plate so as to be engaged with the auxiliary attaching member.

The auxiliary attaching member(s) is(are) conductive, the conductive auxiliary attaching member(s) being made of magnetic material, and the conductive auxiliary attaching member(s) made of magnetic material include at least one groove or protrusion portion. Also, the auxiliary support member is formed by magnetic material, and is supported and fixed in correspondence to the auxiliary attaching member of the tray. A substrate frame is formed at the tray, receives the substrate, and is received in the tray, and a substrate fixing member is formed at the substrate frame and receives the substrate.

In addition, a frame fixing member is formed at the substrate frame so as to be received in the tray. A lower support portion for transportation is further formed at the tray. In the embodiment, an upper support portion is formed at the tray and supplements transportation by the lower support portion.

According to a second aspect of the present invention, an alignment system comprises: a substrate on which deposition materials are deposited; a tray for receiving the substrate, and including at least one fixing holder member; and an alignment plate including a flat plate chuck for pressurizing the substrate, a driver connected to the flat plate chuck for moving the flat plate chuck, and a fixing insertion member engaged with a fixing holder member and the alignment plate for aligning the tray by supporting fixing of the tray.

The fixing holder member includes a through hole having circular shapes of two different diameters overlapping each other. The through hole includes a through hole of smaller diameter and a through hole of larger diameter, the through hole of smaller being positioned at an upper portion of the through hole of larger diameter. The fixing insertion member is inserted in the fixing holder member, and locks and fixes the tray, and a groove is formed at the fixing insertion member, the groove of the fixing insertion member being inserted and mounted in the fixing holder member. Also, at least one auxiliary attaching member is formed at the tray, and an auxiliary support member is formed at the alignment plate so as to be engaged with the auxiliary attaching member. The auxiliary attaching member(s) is(are) conductive. The conductive auxiliary attaching member(s) is(are) made of magnetic material.

The conductive auxiliary attaching member made of magnetic material includes at least one groove or protrusion portion. Also, the auxiliary support member is formed of magnetic material, and is supported and fixed in correspondence to the auxiliary attaching member of the tray. Furthermore, a substrate frame is formed at the tray, receives the substrate, and is received in the tray. A substrate fixing member is formed at the substrate frame and receives the substrate. Furthermore, a frame fixing member is formed at the substrate frame so as to be received in the tray. Also, a lower support portion for transportation is formed at the tray, and an upper support portion is formed at the tray and supplements transportation by the lower support portion.

According to a third aspect of the present invention, a vertical tray transporting assembly comprises: a plate tray for supporting a mask; an upper support portion engaged with an upper side portion of the tray for supporting the tray; a lower support portion engaged with a lower side portion of the tray for supporting the tray; and a plate mask frame arranged between the plate tray and the mask for supporting the mask.

Preferably, the mask frame is made of carbon fiber reinforced plastics (CFRP), and the plate tray is made of Al. Furthermore, the upper support portion includes a guide groove, and the lower support portion has a bar shape. The tray includes a through hole, and the tray is engaged with a mask tray holder through the through hole. An upper portion of the through hole is narrower than a lower portion of the through hole so that the tray is inserted in the through hole. The tray further includes an attaching member arranged at a peripheral portion of the mask so as to improve adhesion force with the substrate.

According to a fourth aspect of the present invention, a deposition apparatus comprises: a process chamber; a mask tray and a substrate tray vertically mounted in the process chamber and parallel to each other, a mask and a substrate being mounted on the mask tray and the substrate tray, respectively; a mask tray conveyer and a substrate tray conveyer for horizontally conveying the mask tray and the substrate tray in parallel with each other; a mask/substrate alignment plate for aligning and adhering the mask and the substrate conveyed by the mask tray conveyer and the substrate tray conveyer, respectively; mask and substrate tray holders for supporting the mask tray and the substrate tray, respectively; and a deposition source for injecting deposition materials into the substrate aligned and adhered to the mask. The mask tray includes a plate tray for supporting the mask, and a plate mask frame arranged between the flat plate tray and the mask for supporting the mask.

Preferably, the mask frame is made of carbon fiber reinforced plastics (CFRP), and the plate tray is made of Al. Furthermore, the substrate tray includes: a plate tray for supporting the substrate; and a plate substrate support member arranged between the plate tray and the substrate for supporting the substrate. The substrate support member is made of carbon fiber reinforced plastics (CFRP), and the plate tray is made of Al.

### BRIEF DESCRIPTION OF THE DRAWINGS

A more complete appreciation of the invention and many of the attendant advantages thereof, will be readily apparent as the same becomes better understood by reference to the following detailed description when considered in conjunction with the accompanying drawings in which like reference symbols indicate the same or similar components.

The above and/or other aspects and advantages of the invention will become apparent and more readily appreciated from the following description of the preferred embodiments, taken in conjunction with the accompanying drawings, in which:

FIG. 1A is a view showing a state of a fixing portion aligned on a substrate;

FIG. 1B is a view showing a state of the fixing portion shown in FIG. 1A lowered onto the substrate;

FIG. 2 is a perspective view schematically showing an alignment system according to a preferred embodiment of the present invention;

FIG. 3 and FIG. 4 are side views showing separated and assembled states, respectively, of the alignment system shown in FIG. 2;

FIG. 5A is an enlarged perspective view of a locking member shown in FIG. 2;

FIG. 5B is a rear view showing a locking hole of the locking member shown in FIG. 5A;

FIG. 5C is an enlarged perspective view of an auxiliary locking member shown in FIG. 2;

FIG. 6A is a front view showing a tray of an alignment system according to another embodiment of the present invention;

FIG. 6B is a rear view showing a tray of an alignment system according to an embodiment of the present invention;

FIG. 6C is a side view showing a tray of an alignment system according to an embodiment of the present invention;

FIG. 7A is a view showing a fixing holder member of an alignment system according to an embodiment of the present invention;

FIG. 7B is a view showing an auxiliary attaching member of an alignment system according to an embodiment of the present invention;

FIG. 8A is a front view showing a substrate, a substrate frame, and a tray in an alignment system according to another embodiment of the present invention;

FIG. 8B is a view showing a state of a substrate separated from a tray of an alignment system according to an embodiment of the present invention;

FIG. 8C is a front view showing a state of a substrate mounted to a tray of an alignment system according to an embodiment of the present invention;

FIG. 9A is a view showing an engaged state of a tray and an alignment plate in an alignment system according to an embodiment of the present invention;

FIG. 9B is a side view showing an engaged state of a tray and an alignment plate in an alignment system according to an embodiment of the present invention;

FIG. 10A is a view showing a state in which a fixing holder member and an auxiliary attaching member of a tray correspond to an insertion member and an auxiliary support member, respectively, of an alignment plate in an alignment system according to another embodiment of the present invention;

FIG. 10B is a view showing an insertion member and an auxiliary support member of an alignment plate that correspond to a fixing holder member and an auxiliary attaching member, respectively, of a tray correspond to an alignment system according to another embodiment of the present invention;

FIG. 11 is a cross-sectional view schematically showing a vertical deposition apparatus according to an embodiment of the present invention;

FIG. 12 is a perspective view showing a vertical mask tray of a vertical deposition apparatus according to an embodiment of the present invention;

FIG. 13 is a cross-sectional view showing a vertical mask tray of a vertical deposition apparatus according to an embodiment of the present invention; and

FIG. 14 is a side view showing a vertical mask tray and a mask tray holder of a vertical deposition apparatus according to an embodiment of the present invention.

### DETAILED DESCRIPTION OF THE INVENTION

Hereinafter, preferable embodiments of the present invention will be described with reference to the accompanying drawings. When one element is connected to another element, one element may not only be directly connected to another element, but may also be indirectly connected to another element via another element. Furthermore, irrelative elements are omitted for clarity. Also, like reference numerals refer to like elements throughout.

Means and a method for fixing and supporting a substrate in the thin film deposition process under vacuum state will now be described with reference to the accompanying drawings.

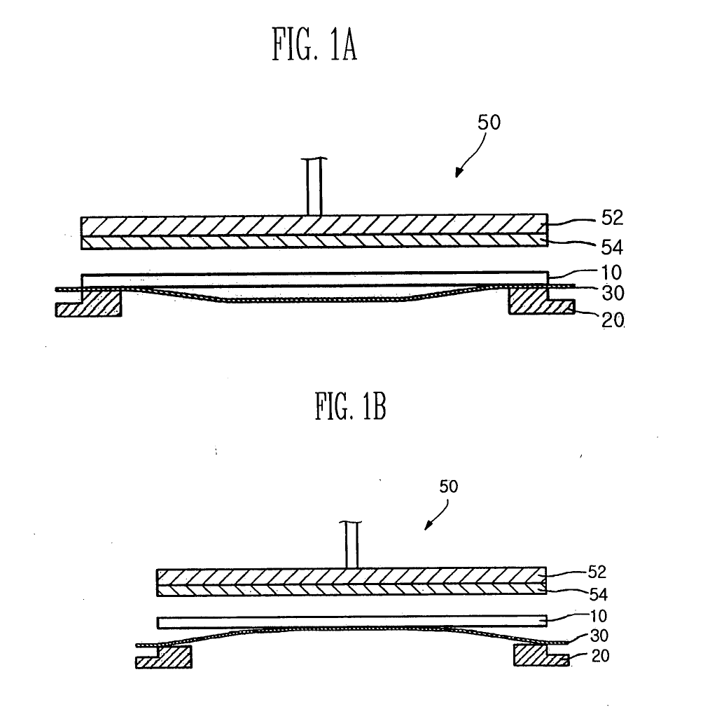

FIG. 1A is a view showing a state of a fixing portion aligned on a substrate. FIG. 1B is a view showing a state of the fixing portion shown in FIG. 1A lowered onto the substrate.

Referring to FIG. 1A and FIG. 1B, a substrate 10 is mounted on a frame 20. A mask 30 is located between the substrate 10 and the frame 20, and has a pattern to be formed. A fixing portion 50 is disposed at an upper portion of the substrate 10, and supports the substrate 10. The fixing portion 50 includes a magnet plate 52 and a rubber magnet 54. The rubber magnet 54 is attached to a lower surface of the magnet plate 52.

The fixing portion 50 is disposed on the substrate 10 by a robot conveyance so as to fix the substrate 10, and mask 30 is aligned with the substrate 10. Next, as shown in FIG. 1B, the fixing portion 50 is lowered onto the substrate 10. When the fixing portion 50 is lowered, the mask 30, which is made of metal, located at a lower portion of the substrate 10 is transformed into the fixing portion 50 so as to have a magnetic force, and is adhered onto the substrate 10. On the other hand, the rubber magnet 54 of the fixing portion 50 is loaded on a rear surface of the substrate 10 and supports the substrate 10. As described above, in a state wherein the mask 30 is adhered to the substrate 10, deposition is performed.

However, when the interval between the mask 30 and the fixing portion 50 becomes narrow, a center part of the mask 30 firstly ascends, thereby causing a mismatch in alignment. Accordingly, the center part of the mask 30 is suitably adhered to the substrate 10, whereas an edge part thereof is wrongly adhered to the substrate 10. As a result, a pattern is formed so as to be deviated from a desired position. This causes the product to be deteriorated. Furthermore, if the center part of the mask 30 ascends ahead of other parts, when the mask 30 is adhered to the substrate 10, sliding occurs. This occurrence of sliding causes the substrate 10 to be damaged. In order to solve the mismatch in alignment, after the mask 30 and the substrate 10 are separated from each other, an alignment is performed again, and then an adhesion is performed. The aforementioned is repeatedly performed. Consequently, the process time is long, and it is difficult to solve the mismatch in alignment.

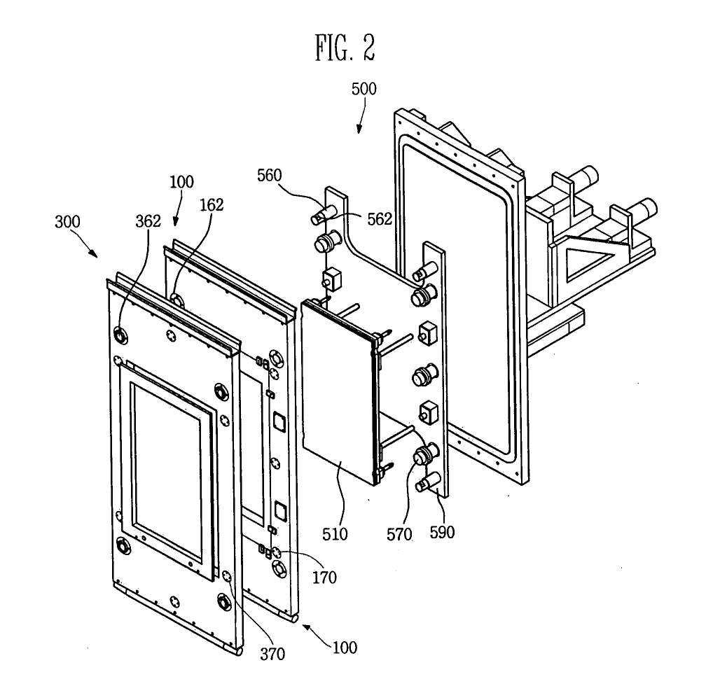

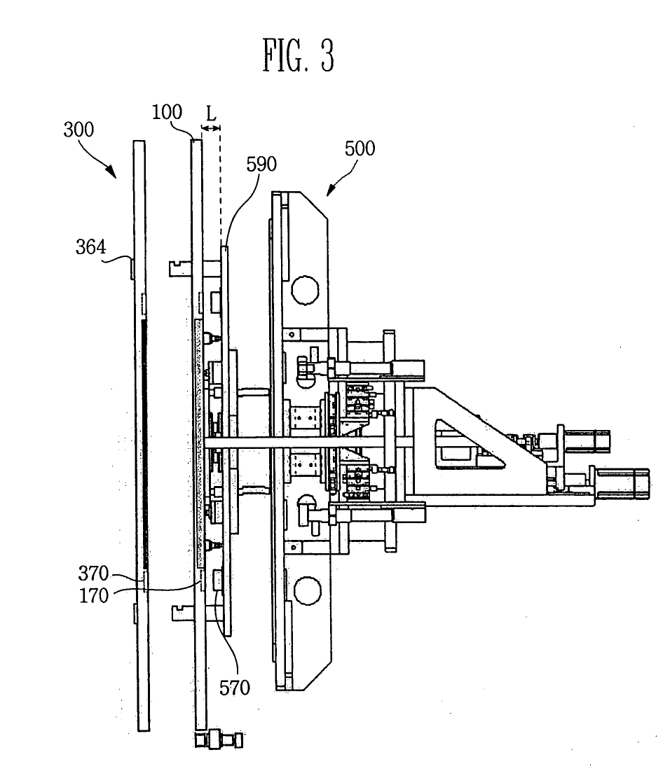

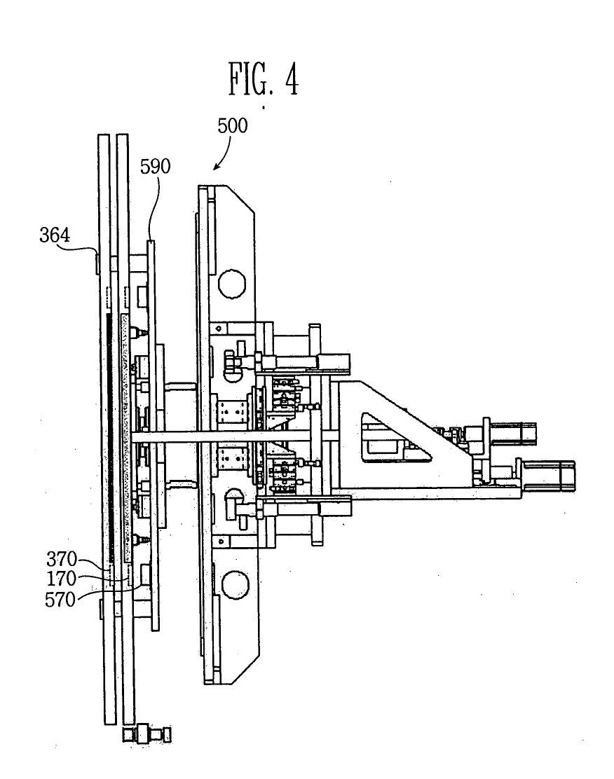

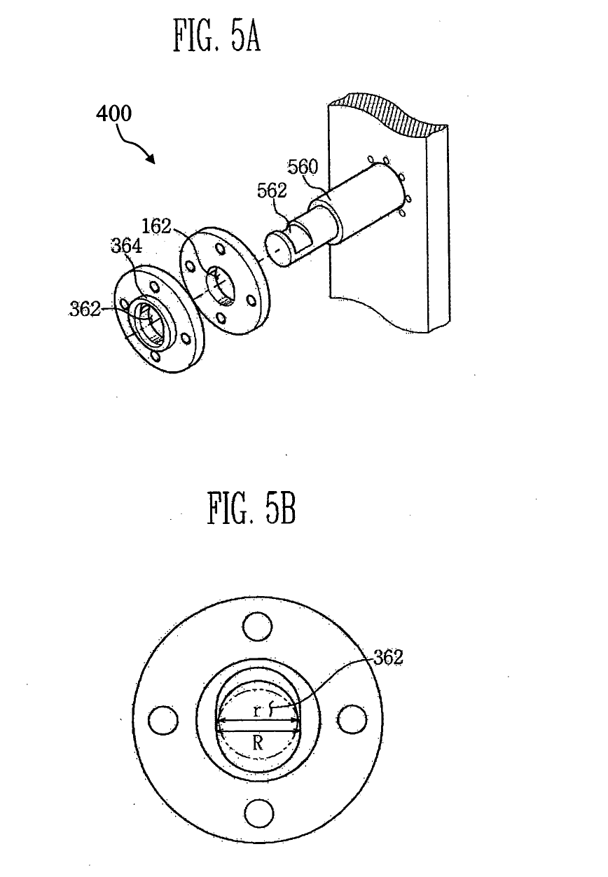

FIG. 2 is a perspective view schematically showing an alignment system according to a preferred embodiment of the present invention. FIG. 3 and FIG. 4 are side views showing separated and assembled states, respectively, of the alignment system shown in FIG. 2. FIG. 5A is an enlarged perspective view of a locking member shown in FIG. 2. FIG. 5B is a rear view showing a locking hole of the locking member shown in FIG. 5A. FIG. 5C is an enlarged perspective view of an auxiliary locking member shown in FIG. 2.

As shown in FIG. 2, in the alignment system of the present invention, a mask tray 300 and a substrate tray 100 are simultaneously stuck to a tray holder 500 by means of a locking member so that the interval or space L between the substrate tray 100 and a holder plate 590 of the tray holder 500 is shortened.

Furthermore, referring to FIGS. 3, 4, 5A and 5B, fixing positions of the substrate tray 100 and the mask tray 300 attached to the tray holder 500 are maintained by means of an auxiliary locking member 400. That is, the locking member 400 includes locking holes 162 and 362, and a locking arm 560 (see FIG. 5A). The locking holes 162 and 362 are formed at the mask tray 300 and the substrate 100. The locking arm 560 is formed at the holder plate 100 of the tray holder 500 so as to be inserted and locked into the locking holes 162 and 362.

The locking arm 560 protrudes from the holder plate 590 (see FIG. 3), and a locking groove 562 (see FIG. 5A) is formed at an upper front end thereof With reference to FIG. 5A and FIG. 5B, a smaller diameter r and a larger diameter R of the locking holes 362 and 162 are formed overlapping each other so as to prevent an interference against a movement of the locking arm 560 in such a manner that a hole having a smaller diameter r of each of the locking holes 362 and 162 is positioned at an upper portion of a hole having a large diameter R thereof, and the smaller diameter r is formed so as to be greater than a minimum diameter of the locking arm 560.

The reason why the smaller diameter r and the larger diameter R of the locking holes 362 and 162 are formed overlapping each other is as follows. The locking arm 560 is easily inserted into the large diameter R of the locking holes 362 and 162, and is then moved to the smaller diameter r so as to be fixed in order to reduce the fluctuation thereof. An upper edge of the locking hole 362 of the mask tray 300 is inserted and locked into the locking groove 562 formed at the locking arm 560.

Furthermore, a support member 364 is formed so as to protrude from an opposite side of an insertion direction of the locking arm 560, and thus the locking hole 362 of the mask tray 300 is included in the formation range of the mask tray 300. In a state wherein the locking hole 362 is locked at the locking groove 562, the support member 364 firmly contacts a part of a head portion of the locking arm 560. This contact causes the locking hole 362 to be tightly locked at the locking groove 562. Furthermore, the support member 364 can be formed at the same substrate tray 100 as the mask tray 300. The difference is that the support member 364 is disposed in an insertion direction of the locking arm 560. The mask tray 300 and the substrate tray 100 are locked into the locking arm 560, so that the interval L between the substrate 100 and the holder plate 590 is reduced to the maximum extent, as seen in FIG. 3.

On the other hand, with reference to FIGS. 3, 4 and 5A thru 5C, auxiliary locking portion 400 continues to maintain a fixed state of the mask tray 300, the substrate tray 100 and the holder plate 590 in that the locking arm 560 is locked in the locking holes 362 and 162 of the mask tray 300 and the substrate tray 100. As seen in FIG. 5C, the auxiliary locking portion 400 includes magnetic materials 370, 170 and 570. The magnetic materials 370, 170 and 570 are arranged to sequentially provide a reciprocal attractive force with respect to the mask tray 300, the substrate tray 100 and the holder plate 590.

The magnetic substances 370, 170 and 570 are preferably fixed to two trays 300 and 100, and the holder plate 590 in the same line. The magnetic substances 370, 170 and 570 are attached to the mask tray 300 and the substrate tray 100 so as to define the same outer surface. The magnetic material 570 is fixed to the holder plate 590 and is formed so as to protrude in the vicinity of the magnetic substance 170 of the substrate tray 100 so that the interval L between the holder plate 590 and the substrate tray 100 is shortened. The locking arm 560 and the magnetic substance 570 fixed to the holder plate 590 of the tray holder 500, the locking holes 362 and 162, and the magnetic materials 370 and 170 are preferably formed at four corners.

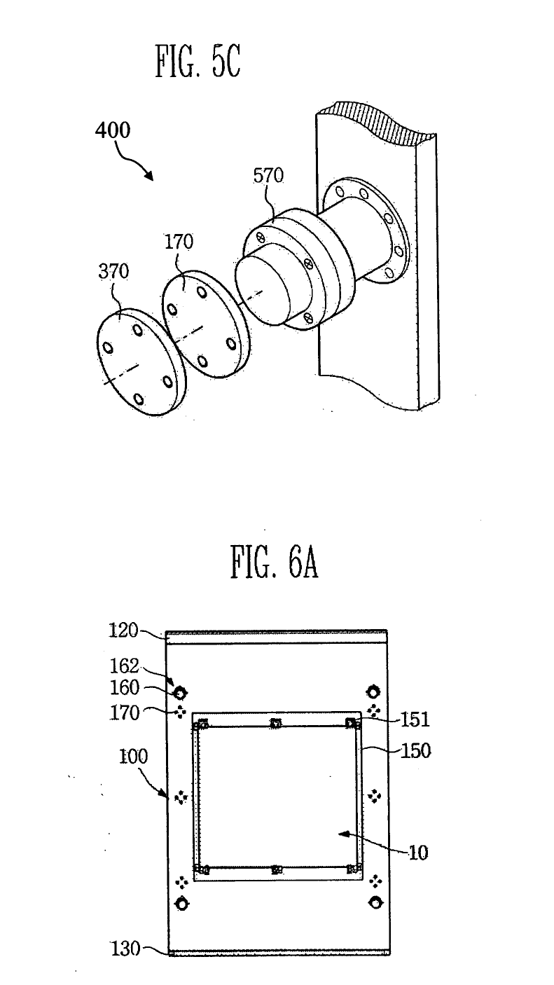

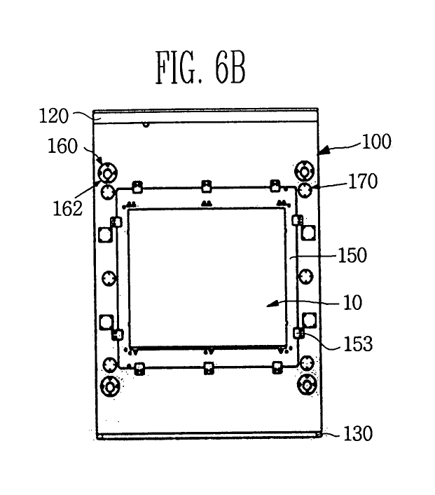

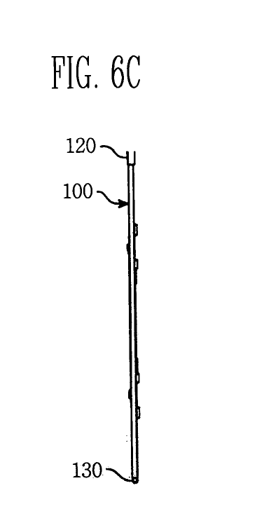

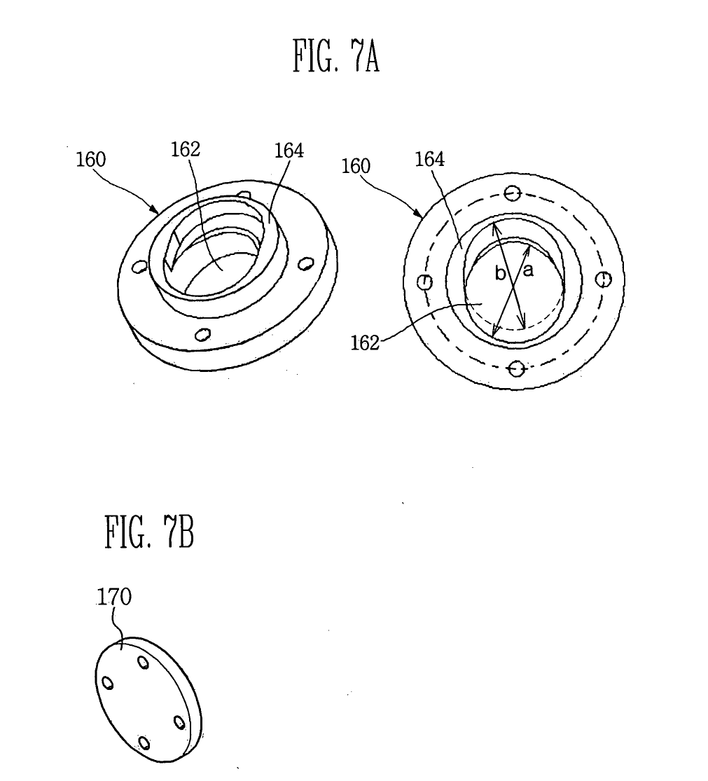

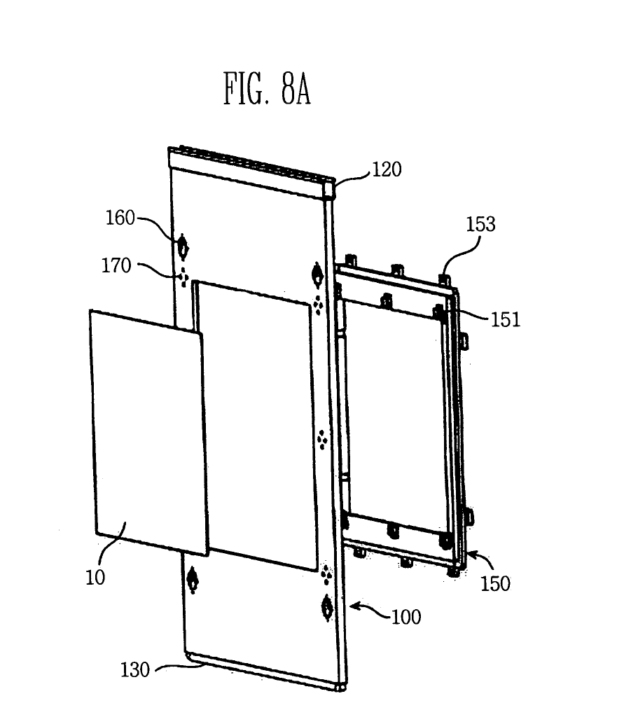

FIG. 6A is a front view showing a tray of an alignment system according to another embodiment of the present invention. FIG. 6B is a rear view showing a tray of an alignment system according to another embodiment of the present invention. FIG. 6C is a side view showing a tray of an alignment system according to another embodiment of the present invention.

Referring to FIG. 6A thru FIG. 6C, the tray of an alignment system according to another embodiment of the present invention includes a substrate 10 and a flat plate type tray 100. Deposition materials are deposited on the substrate 10. The tray 100 receives the substrate 10, and includes at least one fixing holder member 160.

The flat type tray 100 is designed so as to be suitable to receive the substrate frame 150, and includes a frame fixing member 153 to be fixed to the tray 100. The substrate frame 150 received in the tray 100 is designed so as to be suitable to receive the substrate 10, and includes a substrate fixing member 151 for fixing the substrate 10. A lower support portion 130 is formed at a lower portion of the tray 100 which allows the substrate 10 to transfer in a vacuum chamber. An upper support portion 120 is formed at an upper portion of the tray 100, and guides the transfer of the lower support portion 130. A plurality of fixing holder members 160 and attaching members 170 are formed around a peripheral region of the substrate frame 150 on a flat plate of the tray 100. A through hole 162 is formed at each of the fixing holder members 162.

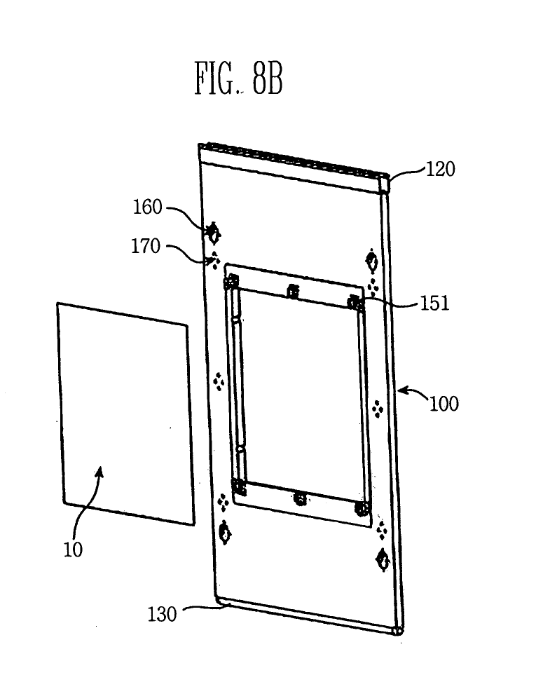

FIG. 7A is a view showing a fixing holder member of an alignment system according to another embodiment of the present invention. As described previously with reference to FIGS. 6A and 6B, at least one fixing holder member 160 is formed around a peripheral region of the substrate frame 150 on a flat plate of the tray 100. A stepped portion 164 (FIG. 7A) is formed at a surface opposite to an attached surface of the fixing holder member 160 to the tray 100 so as to protrude outward from the tray 100. The through hole 162 of the fixing holder member 160 has a side attached to the tray 100. A first inner diameter a of the side of the through hole 162 is formed in a circular shape. A second inner diameter b of the stepped portion 164 overlaps the first inner diameter a of the side of the through hole 162 attached to the tray 100. A circle formed by the inner diameter a pierces the fixing holder member 160. It is preferred that sizes of the first inner diameter a and the second inner diameter b be different from each other. More preferably, the first inner diameter a is greater than the second inner diameter b, and the second inner diameter b is positioned at an upper portion of the first inner diameter a.

FIG. 7B is a view showing an auxiliary attaching member of an alignment system according to another embodiment of the present invention. As mentioned above with reference to FIGS. 6A and 6B, a plurality of auxiliary attaching members 170 are formed around a peripheral region of the substrate frame 150 on a flat plate of the tray 100. A surface of the auxiliary attaching member 170 is a flat plate type surface, and the auxiliary attaching member 170 includes an additional arrangement so as to be tightly stuck to the tray 100. A surface opposite to an attached surface of the auxiliary attaching member 170, namely, a surface which protrudes outward from the tray 10, is also formed as a flat plate type surface. A groove having a negative angle or a small protrusion having a positive angle may be further provided so as to conform to a counter member attached to the auxiliary attaching member 170. The auxiliary attaching member 170 is preferably made of conductive materials, and is more preferably made of conductive materials having magnetic characteristics.

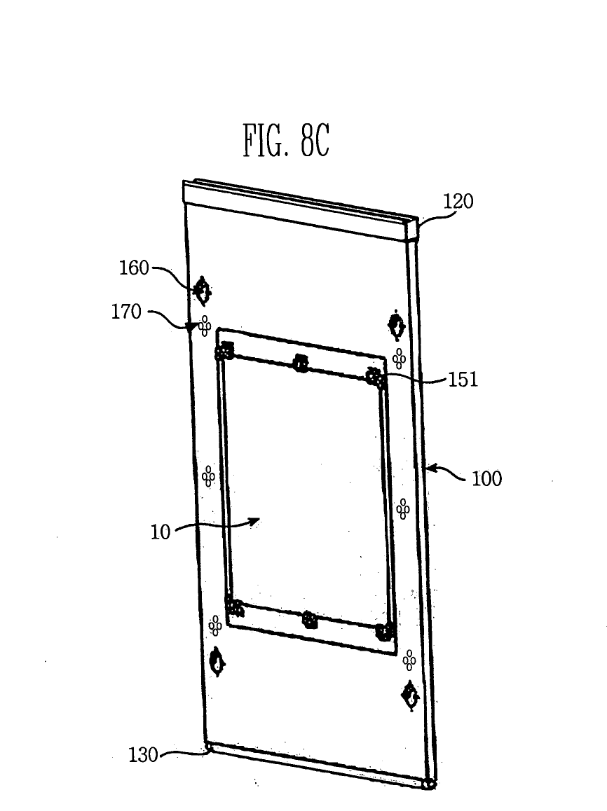

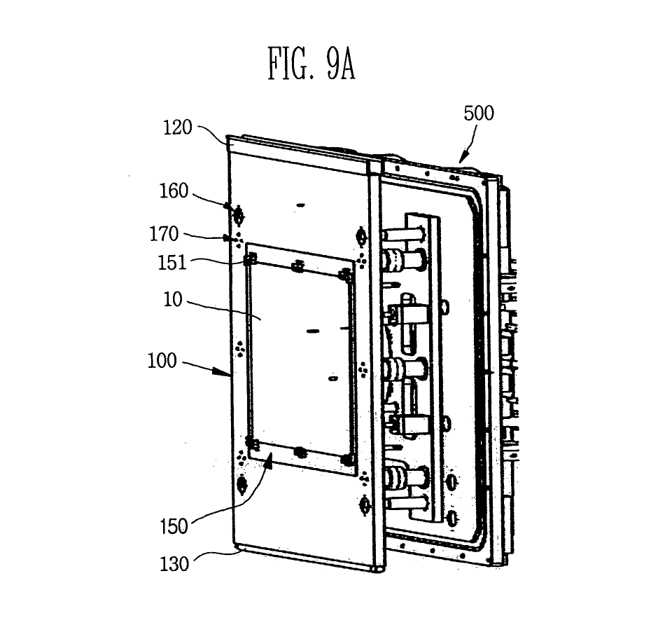

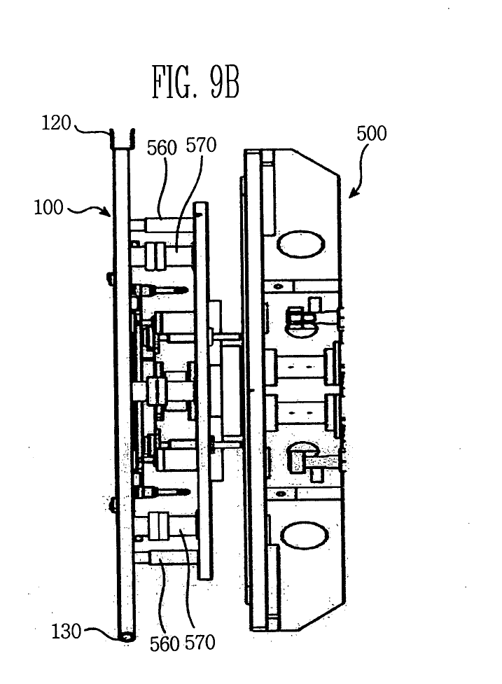

The operation of the alignment system according to an embodiment of the present invention will now be described with reference to the accompanying drawings. FIG. 8A is a front view showing a substrate, a substrate frame and a tray in an alignment system according to another embodiment of the present invention. FIG. 8B is a view showing a state of a substrate separated from a tray of an alignment system according to another embodiment of the present invention. FIG. 8C is a front view showing a state of a substrate mounted to a tray of an alignment system according to another embodiment of the present invention.

With reference to FIG. 8A thru FIG. 8C, the substrate frame 150 is engaged with a front surface of the tray 100, and the substrate 10 is engaged with the substrate frame 150 at a rear surface of the tray 100. The substrate frame 150 is engaged in an opening formed at a center portion of the tray 100 and is fixed to the tray 100 by the frame support member 153 (see FIG. 8B). The substrate 10 is then engaged in an opening formed in the substrate frame 150, and is fixed to the substrate frame 150 by the substrate fixing member 151. The substrate frame 150 and the substrate 10 are thus engaged to the tray 100 which results in the completion of a tray for fixing the substrate 10 (see FIG. 8C).

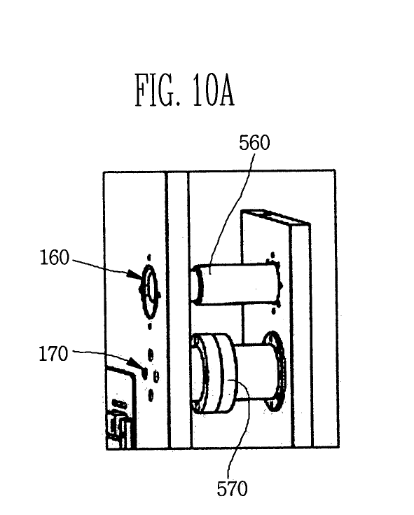

FIG. 9A is a view showing an engaged state of a tray and an alignment plate in an alignment system according to another embodiment of the present invention. FIG. 9B is a side view showing an engaged state of a tray and an alignment plate in an alignment system according to another embodiment of the present invention.

Referring to FIG. 9A, the tray 100 is attached to an alignment plate 500 so as to perform a vacuum deposition. The alignment plate 500 includes a flat plate chuck (not shown), a driving means (not shown), and a fixing insertion member 160. The flat plate chuck pressurizes the substrate 10 to a shadow mask (not shown). A pattern of the shadow mask is formed at an introducing direction of deposition materials. The driving means is connected to the flat plate chuck, and moves the flat plate chuck. The fixing insertion member 560 (FIG. 9B) is engaged with the fixing holder member 160 (FIG. 9A). The shadow mask is attached to the tray 100 which is attached to the alignment plate 500 so as to perform a deposition. At this time, a deposition pattern is formed according to the pattern of the shadow mask. Prior to forming such a deposition pattern, an alignment between the substrate 10 mounted on the tray 10 and the shadow mask is achieved. In order to achieve such an alignment, the alignment plate 500 moves the tray 100, on which the substrate 10 is mounted, in a plurality of directions which allows the tray 100 to match with the shadow mask.

With reference to FIGS. 9A and 9B, a fixing holder member 160 of the alignment system according to an embodiment of the present invention is engaged with a fixing insertion member 560 of an alignment plate 500. An auxiliary attaching member 170 of tray 100 is engaged with an auxiliary support member 570 of the alignment plate 500. The fixing insertion member 560 is inserted in the fixing holder member 160 of the tray 100 so as to lock and fix the tray 100. A groove (not shown) is preferably formed in the fixing insertion member 560 so that the fixing insertion member 560 is inserted in the fixing holder member 160 through the groove. The auxiliary support member 570 is formed of a magnetic substance, and is supported and fixed in correspondence to the auxiliary attaching member 170 of the tray 100.

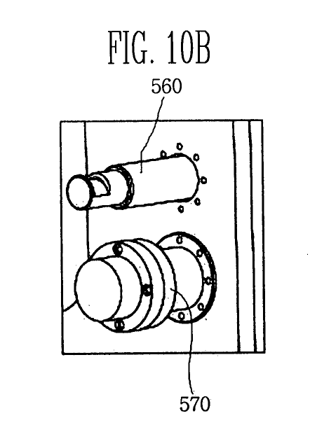

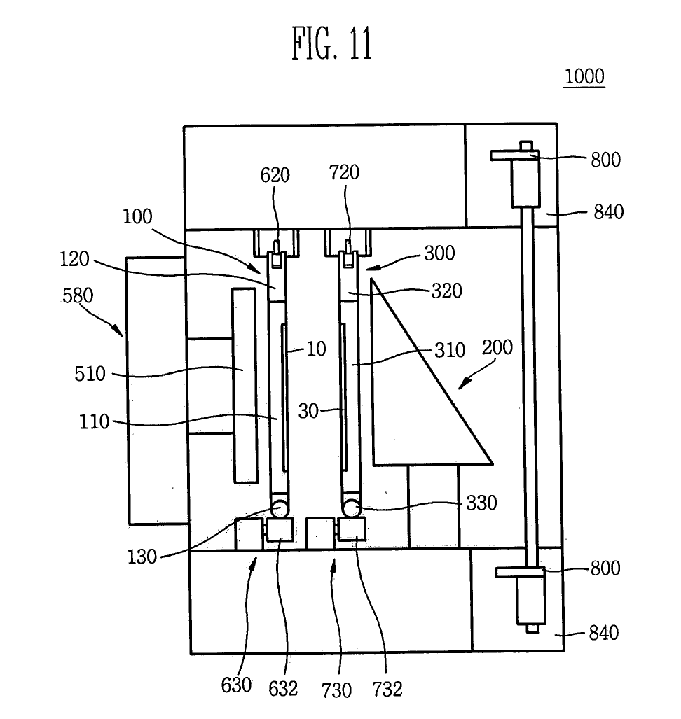

FIG. 10A is a view showing a state in which a fixing holder member and an auxiliary attaching member of a tray correspond to an insertion member and an auxiliary support member, respectively, of an alignment plate in an alignment system according to another embodiment of the present invention. FIG. 10B is a view showing an insertion member and an auxiliary support member of an alignment plate that correspond to a fixing holder member and an auxiliary attaching member, respectively, of a tray in an alignment system according to another embodiment of the present invention.

With reference to FIG. 10A and FIG. 10B, the fixing insertion member 560 of the alignment plate 500 (FIG. 9B) has a bar shape. The fixing insertion member 560 includes a stepped portion having a smaller diameter in a protrusion direction, namely, a direction toward the tray 100 (FIG. 9B). A smaller diameter part of the fixing insertion member 560 has a size small enough to be inserted in the first inner diameter a of a through hole 162 (FIG. 7A) of the fixing holder member 160. Furthermore, a groove (not shown) is formed as a half-circle of one side of the smaller diameter part thereof.

When the tray 100 is attached to the alignment plate 500 (FIGS. 9A and 9B), the fixing insertion member 560 of FIGS. 10A and 10B is inserted into a through hole 162 of a corresponding fixing holder member 160. After a front end of the fixing insertion member 560 is inserted into the first inner diameter a (FIG. 7A) of the through hole 162 of the fixing holder member 160, the groove formed in the smaller diameter part of the fixing insertion member 560 is engaged with a surface formed by the first inner diameter a of the through hole 162, whereby the surface of the second inner diameter b (FIG. 7A) comes into contact with part of a formation portion in the smaller diameter part of the fixing insertion member 560. The groove is formed in a smaller diameter part, and corresponds to a thickness of the surface formed by the first inner diameter a of the through hole 162. When the tray 100 is attached to the alignment plate 500, the fixing insertion member 560 is inserted into and engaged with the fixing holder member 160, whereby the tray 100 may be stably fixed and supported so as to allow alignment of high precision.

The auxiliary support member 570 of the alignment plate 500 has an area of sufficient size to contact the auxiliary attaching member 170 of the tray 100. The auxiliary support member 570 includes a magnetic force generation source (not shown) which attracts the auxiliary attaching member 170 made of conductive and magnetic materials. Preferably, in order to easily separate the auxiliary attaching member 170 from the auxiliary support member 570 after termination of process, the magnetic force generation source is an electromagnet.

Upon attaching the tray 100 to the alignment plate 500, the auxiliary attaching member 170 is attached to a corresponding auxiliary support member 570, so that the tray 100 is stably fixed and supported which allows alignment of high precision. Moreover, concave and convex portions are formed in the auxiliary support member 570 and the auxiliary attaching member 170 in correspondence to each other. The concave and convex portions function to guide the auxiliary support member 570 and the auxiliary attaching member 170 during the attachment operation. Moreover, the concave and convex portions increase the contact area so as to more tightly and exactly attach the auxiliary support member 570 to the auxiliary attaching member 170.

A description of the operation of the alignment system according to the present invention will now be provided. When tray holder 500 operates by means of a driver, a locking arm 560 of holder plate 590 (FIG. 2) is inserted into and locked in locking holes 362 and 162 of a mask tray 300 and a substrate tray 100, respectively. At this point, a locking groove 562 (FIG. 5A) formed in the locking arm 560 is inserted in an edge of the locking hole 362 of the mask tray 300, and a support member 364 formed in the mask tray 300 contacts a head portion of the locking arm 560. This contact supplements the locking groove 562 and the locking hole 362 of the mask tray 300 so as to be tightly locked. Furthermore, in a state in which the mask tray 300 and the substrate tray 100 are tightly locked to the holder plate 590 for alignment by means of a magnetic chuck 510 (FIG. 2), a mutual attractive force is provided between the mask tray 300, the substrate tray 100 and the holder plate 590 by magnetic substances 370, 170 and 570, respectively, thereby stably maintaining an alignment state. Moreover, the substrate tray 100 and the holder plate 590 are positioned in the vicinity of each other, thereby causing the temperature of the substrate tray 10 to be reduced by the holder plate 590.

An embodiment of a vertical tray transporting assembly and a deposition apparatus according to the present invention will now be explained by reference to accompanying drawings.

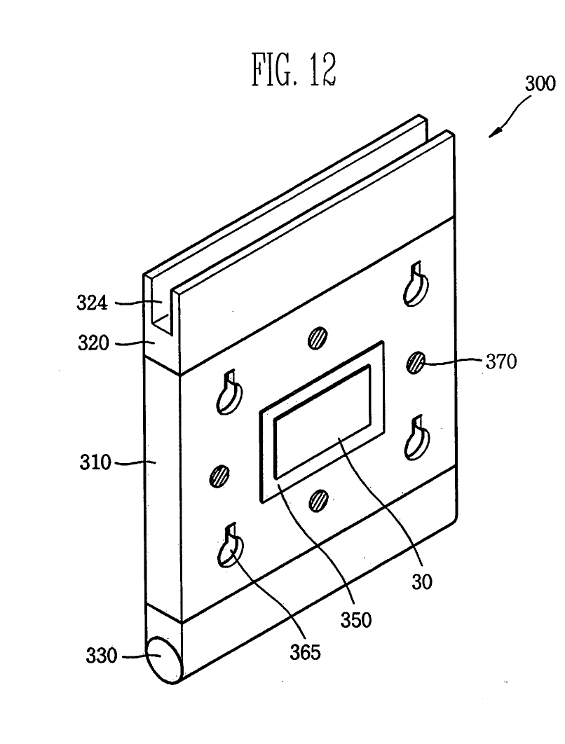

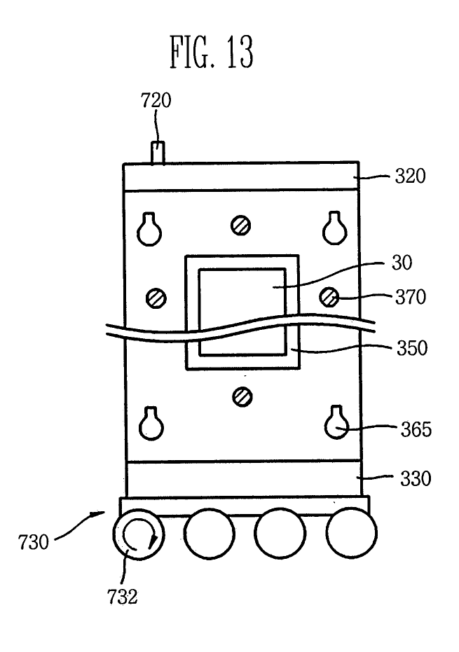

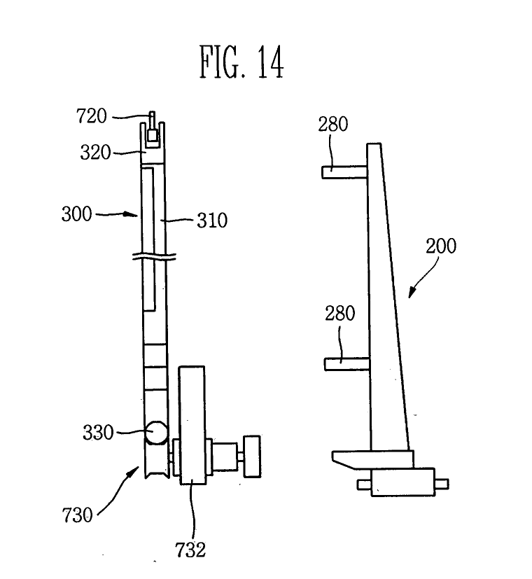

FIG. 11 is a cross-sectional view schematically showing a vertical deposition apparatus according to an embodiment of the present invention; FIG. 12 is a perspective view showing a vertical mask tray of a vertical deposition apparatus according to an embodiment of the present invention; FIG. 13 is a cross-sectional view showing a vertical mask tray of a vertical deposition apparatus according to an embodiment of the present invention; and FIG. 14 is a side view showing a vertical mask tray and a mask tray holder of a vertical deposition apparatus according to an embodiment of the present invention.

With reference to FIG. 11, the deposition apparatus of the present invention includes a process chamber 1000, a mask tray 300, a substrate tray 100, a mask tray holder 200, and a substrate tray holder 510. The mask tray 300 and the substrate tray 100 are mounted in the process chamber 1000. The deposition apparatus further includes a mask tray conveyer 730, a substrate tray conveyer 630, a mask/substrate alignment plate 580, and a deposition source 800. The mask tray 300 mounts a thin film deposition mask in a vertical pattern and transports it in the process chamber 1000. The substrate tray 300 holds a substrate (not shown) on which a thin film is deposited, namely, a deposited substrate in a vertical pattern, and transports it in the process chamber 1000.

As shown in FIG. 12 and FIG. 13, the mask tray 300 includes a plate tray 310, an upper support portion 320, and a lower support portion 330. The plate tray 310 supports a mask 30. The upper support portion 320 is engaged with an upper side portion of the tray 310, and supports the tray 310. The lower support portion 330 is engaged with a lower side portion of the tray 310, and supports the tray 310.

The upper support portion 320 includes a guide groove 324. As shown in FIG. 11 and FIG. 14, an upper guide 720 of the mask tray conveyer 730 is inserted into the guide groove 324 (FIG. 12) of the upper support portion 320. The lower support portion 330 is formed in a bar shape and is engaged with a driver 732 of the mask tray conveyer 730, as shown in FIG. 11 and FIG. 14. The upper guide 720 of the mask tray conveyer 730 is formed so as to have a bearing shape, and is inserted into guide groove 324 of the upper support portion 320 of the mask tray 300. The driver 732 is embodied as a roller, and is engaged with the lower support portion 330 of the mask tray 300. Moreover, the mask tray 300 further includes a mask frame 350 (FIG. 12) for supporting the mask 30.

The mask frame 350 is formed as a plate type of high precision, and is adhered to the tray 310. The mask frame 350 is made of carbon fiber reinforced plastics (referred to as ‘CFRP’ hereafter). The mask frame 350 is arranged in the tray 310, and the mask 30 is arranged in the mask frame 350. In the embodiment of the present invention, the mask frame 350 for supporting the mask 30 may include CFRP, and the tray 310 may be made of aluminum or CFRP. In this case, the mask tray 300 may be lightweight. In addition, the mask tray 300 includes a plate tray 310 in which a through hole 365 is formed. An insertion protrusion 280 (see FIG. 14) of a mask tray holder 200 is inserted in the through hole 365 (FIG. 12) so that the mask tray 300 is supported by the mask tray holder 200. The through hole 365 permits the insertion protrusion 280 of the mask tray holder 200 to be easily inserted. After insertion of the insertion protrusion 280, the through hole 365 causes the mask tray 300 to be fixed without movement. For these purposes, an upper portion of the through hole 365 is preferably formed so as to be narrower than a lower portion thereof. Moreover, an attaching member 370 (FIG. 12) is attached to the mask tray 300. The attaching member 370 functions to increase an adhesion force between the substrate tray 100 and the mask tray 300 during alignment and coherence processes of the substrate tray 100 and the mask tray 300. Although the substrate tray 100 is not shown in FIG. 14, as in the mask tray 300, a substrate support member of high precision for supporting the substrate may be provided in the substrate tray 100, and the substrate support member supports the substrate.

In the same manner, the substrate tray 100 includes a plate tray 110 (FIG. 11), an upper support portion 120, and a lower support portion 130. The upper support portion 120 is engaged with an upper side portion of the tray 110, and supports the tray 110. The lower support portion 130 is engaged with a lower side portion of the tray 110, and supports the tray 110. The upper support portion 120 includes a guide groove. An upper guide 620 of the substrate tray conveyer 630 is inserted into the guide groove of the upper support portion 120. The lower support portion 130 has a bar shape, and is engaged with a driver 632 of the substrate tray conveyer 630. The mask tray holder 200 functions to support the mask tray 300 conveyed by the mask tray conveyer 730. The substrate tray holder 510 functions to support the substrate tray 100 conveyed by the substrate tray conveyer 630.

When the substrate tray 100 is loaded onto the substrate tray holder 510, the mask tray holder 200 supports the mask tray 300, and moves the mask tray 300 to the substrate tray holder 510 on which the substrate tray 100 is mounted, thereby joining a substrate 10 mounted on the substrate tray 110 and a mask. At this point, as shown in FIG. 14, an insertion 280 of the mask holder 200 is inserted into a through hole 365 of the mask tray 300, thereby fixing the mask tray 300.

The mask tray conveyer 730 includes a driver 732 and an upper guide 720. The driver 732 includes a roller 330 installed at a bottom portion of the mask tray 300. The upper guide 720 is formed to have a bearing shape and horizontally moves the mask tray 300. In the same manner, the substrate tray conveyer 630 (FIG. 11) includes a driver 632 and an upper guide 620. The driver 632 includes a roller 130 installed at a lower portion of the substrate tray 100. The upper guide 620 is formed to have a bearing shape and horizontally moves the substrate tray 100.

Although it is not shown in drawings, the mask tray conveyer 730 further includes an elevator. The elevator is installed at a lower side of the mask tray 300. The elevator is supported by the upper guide 720 through expansion or elevation operation, and elevates the mask tray 300 that has been stopped at a predetermined position in the process chamber 1000. Accordingly, the mask tray holder 200 moves the mask tray 300, elevated by the elevator, in a direction of the substrate tray 100 without interference with the driver 732, so that the mask 30 is adhered to the substrate 10.

In the same manner, the substrate tray conveyer 630 further includes an elevator (not shown). The elevator is provided at a lower side of the substrate tray 100. The elevator is supported by the upper guide 620 through expansion or elevation operation, and elevates the substrate tray 100 which has been stopped at a predetermined position in the process chamber 1000. Accordingly, the substrate tray 100, elevated by the elevator, is attached to the substrate tray holder 510 and a mask/substrate alignment plate 580. During the elevating operation of the elevator, because the upper guide 620 is integrally elevated with the elevator, it is preferred that the substrate tray holder 510 be designed so as not to interfere with the substrate tray 100.

The deposition apparatus of the present invention further includes a deposition source 800. The deposition source 800 radiates deposition materials injected from a nozzle (not shown) to the substrate 10 uniformly. The deposition source further includes a buffer chamber 840 as a deposition source. While a film formation process is not being performed, the buffer chamber 840 receives a deposition material so as to maintain a desired film formation rate.

A method for vertically depositing a thin film, for example, an organic thin film, using the deposition apparatus described above will now be explained.

First, the mask 30 is mounted on the mask tray 300, and the mask tray 300 with the mask 30 mounted thereon is transported into the process chamber 1000. At this point, the mask tray 300 with the mask 30 mounted thereon is preferably loaded into the process chamber 1000 in a vertical pattern. The mask tray 300, transported into the process chamber 1000, is vertically conveyed by the mask tray conveyer 730, and is supported by the mask tray holder 300. A bearing of the upper guide 732 of the mask tray conveyer 730 is inserted in the guide groove of the lower support portion 330 of the mask tray 300, and the lower support portion 330 is engaged with the driver 720 so as to be moved horizontally.

After the mask loading process, the substrate 10 is transported into the process chamber 1000. At this time, the substrate tray 100 with the substrate mounted thereon is preferably loaded in the process chamber 1000 in a vertical pattern. The substrate tray 100, transported into the process chamber 1000, is vertically conveyed by the substrate tray conveyer 630, and is supported by the substrate tray holder 510 and a mask substrate/alignment plate 580. A bearing of the upper guide 620 of the substrate tray conveyer 730 is inserted into the guide groove 124 of the upper support portion 120 of the substrate tray 300, and the lower support portion 130 is engaged with the driver 632 so as to be horizontally moved. At this point, the loaded mask 30 and substrate 10 maintain a vertical state and are parallel to each other. Since the mask 30 is supported by a support member 350 of high precision in the mask tray 300, and the substrate 10 is supported by a support member of high precision in the substrate tray 100, bending occurs due to the self weight of a mask and a substrate.

When a loading process of the mask 30 and the substrate 10 is terminated, a process of aligning and adhering the mask 30 and the substrate 10 starts. In a state in which the loaded mask 30 and substrate 10, maintained in the vertical state and parallel to each other, are respectively mounted at the mask tray 300 and the substrate tray 100, the alignment/adhesion process is performed.

After the alignment/adhesion process, a film formation process begins. In a state in which the mask 30 and the substrate 10 are vertically aligned/adhered, while a linear deposition source is moved up and down, namely, in the vertical direction, deposition materials are injected so as to form a film on the substrate 10.

Next, a process for separating the mask 30 and the substrate 10 is carried out. The mask 30 and the substrate 10 are preferably separated in a state in which they are mounted in the mask tray 300 and the substrate tray 100, respectively.

Then, after the substrate 10 with the deposition materials formed thereon is transported into a next process chamber for a next process, a new substrate to be formed by deposition materials is transported into the process chamber 1000, and the aforementioned operation is repeated.

Embodiments of the present invention have been described with respect to a vertically linear deposition source as the deposition source 800, but the deposition source 800 is not limited to the above. For example, various spot deposition sources or other various deposition sources, arranged to obtain deposition effects using a linear deposition source, may be employed for the purpose.

As mentioned above, in the alignment system, the vertical tray transporting assembly and the deposition apparatus with the same, according to the present invention, a mask tray and a substrate tray are stably locked to each other in a tray holder through a locking arm of the mask tray and locking holes of the substrate tray, thereby securing a stable alignment position. The stable alignment position of the tray holder, the mask tray and the substrate tray is firmly maintained by magnetic materials so as to prevent the trays from being shaken. A holder plate of the tray holder reduces a temperature of the substrate tray so as to stabilize a magnetic force formed between the magnetic substances, whereby a precise and exact alignment of the trays is achieved.

Furthermore, a contact plate of high precision, including CFRP, supports the mask and the substrate so as to prevent the mask and the substrate from being bent, and cause the mask and the substrate to be lightweight. Moreover, a mask and a bearing of a substrate conveyer are inserted into guide grooves formed at a mask and an upper support portion of a substrate tray, respectively, and a mask and a lower support portion of a mask tray having a bar shape are engaged with a driver so as to be horizontally moved, thus minimizing the effect of fine particles due to a movement of the tray. In addition, because the mask and the substrate are moved by a mask tray and a substrate tray, respectively, the substrate and the mask can be protected.

Although several embodiments of the present invention have been shown and described, it will be appreciated by those skilled in the art that changes may be made in this embodiment without departing from the principles and spirit of the invention, the scope of which is defined in the claims and their equivalents.

What is claimed is:

1. An alignment system, comprising:
a substrate vertically installed and to which a substrate is stuck;
a mask tray vertically aligned in correspondence to the substrate tray, and to which a mask is stuck; and
a tray holder;
wherein the substrate tray and the mast tray are locked to the tray holder by means of a locking portion.

2. The alignment system according to claim 1, wherein the locking portion includes locking holes formed in the substrate tray and the mask tray, respectively, and a locking arm formed in the tray holder and inserted and locked in the locking holes.

3. The alignment system according to claim 2, wherein the locking arm includes a locking groove, and a part of an edge of the locking hole of the mask tray is inserted into the locking groove.

4. The alignment system according to claim 3, wherein the locking hole of the mask tray is formed by two holes having different diameters and overlapping each other.

5. The alignment system according to claim 4, wherein the locking hole of the mask tray has holes of smaller and larger diameters, respectively, overlapping each other so as to prevent interference due to a movement of the locking arm, a hole of smaller diameter being positioned at an upper portion of a hole of larger diameter.

6. The alignment system according to claim 4, wherein the mast tray further includes a support member formed so as to protrude from an opposite side of an insertion direction of the locking arm, and wherein a part of the support member contacts a head end of the locking arm.

7. The alignment system according to claim 2, wherein the locking hole of the mask tray is formed by two holes having different diameters and overlapping each other.

8. The alignment system according to claim 7, wherein the locking hole of the mask tray has holes of smaller and larger diameters, respectively, overlapping each other so as to prevent interference due to a movement of the locking arm, a hole of smaller diameter being positioned at an upper portion of a hole of larger diameter.

9. The alignment system according to claim 7, wherein the mast tray further includes a support member formed so as to protrude from an opposite side of an insertion direction of the locking arm, and wherein a part of the support member contacts a head end of the locking arm.

10. The alignment system according to claim 1, wherein the tray holder includes a holder plate driven by a driver and arranged in a vicinity of the substrate tray.

11. The alignment system according to claim 1, further comprising an auxiliary locking portion for maintaining locking positions of the mask tray and the substrate tray locked to the tray holder.

12. The alignment system according to claim 11, wherein the auxiliary locking portion includes a magnetic substance for sequentially providing a mutual attractive force between the substrate tray, the mask tray and the tray holder.

13. The alignment system according to claim 12, wherein a magnetic substance of the tray holder is installed in a holder plate.

14. The alignment system according to claim 10, wherein a magnetic substance of the tray holder is installed in a holder plate.

15. The alignment system according to claim 1, wherein the substrate tray includes at least one fixing holder member.

16. The alignment system according to claim 15, wherein the fixing holder member includes a through hole having circular shapes of two different diameters overlapping each other.

17. The alignment system according to claim 16, wherein the through hole includes a through hole of smaller diameter and a through hole of larger diameter, the through hole of smaller being positioned at an upper portion of the through hole of larger diameter.

18. The alignment system according to claim 1, wherein the tray holder comprises:
a flat plate chuck for pressurizing the substrate;
a driver connected to the flat plate chuck for moving the flat plate chuck; and
a fixing insertion member engaged with a fixing holder member.

19. The alignment system according claim 18, wherein the fixing insertion member is inserted in the fixing holder member, and locks and fixes the tray.

20. The alignment system according to claim 19, wherein a groove is formed in the fixing insertion member, and the groove of the fixing insertion member is inserted into and mounted in the fixing holder member.

21. The alignment system according to claim 15, wherein at least one auxiliary attaching member is formed in the tray, and an auxiliary support member is formed in an alignment plate to be engaged with said at least one auxiliary attaching member.

22. The alignment system according to claim 21, wherein said at least one auxiliary attaching member is conductive.

23. The alignment system according to claim 22, wherein said at least one auxiliary attaching member is made of magnetic material.

24. The alignment system according to claim 23, wherein said at least one auxiliary attaching member made of magnetic material includes one of at least one groove and at least one protrusion portion.

25. The alignment system according to claim 24, wherein the auxiliary support member is formed of magnetic material, and is supported and fixed in correspondence to the said at least one auxiliary attaching member.

26. The alignment system according to claim 23, wherein the auxiliary support member is formed of magnetic material, and is supported and fixed in correspondence to the said at least one auxiliary attaching member.

27. The alignment system according to claim 22, wherein the auxiliary support member is formed of magnetic material, and is supported and fixed in correspondence to the said at least one auxiliary attaching member.

28. The alignment system according to claim 21, wherein the auxiliary support member is formed of magnetic material, and is supported and fixed in correspondence to the said at least one auxiliary attaching member.

29. The alignment system according to claim 21, wherein a substrate frame is formed at the tray, receives the substrate, and is received in the tray.

30. The alignment system according to claim 29, wherein a substrate fixing member is formed at the substrate frame and receives the substrate.

31. The alignment system according to claim 30, wherein a frame fixing member is formed at the substrate frame to be received in the tray.

32. The alignment system according to claim 31, wherein a lower support portion for transportation is further formed at the tray.

33. The alignment system according to claim 31, wherein an upper support portion is formed at the tray and supplements transportation by the lower support portion.

34. An alignment system, comprising:
a substrate on which deposition materials are deposited;
a tray for receiving the substrate, and including at least one fixing holder member; and
an alignment plate including a flat plate chuck for pressurizing the substrate, a driver connected to the flat plate chuck for moving the flat plate chuck, and a fixing insertion member engaged with a fixing holder member and the alignment plate for aligning the tray by supporting fixing the tray.

35. The alignment system according to claim 34, wherein the fixing holder member includes a through hole having circular shapes of two different diameters overlapping each other.

36. The alignment system according to claim 35, wherein the through hole includes a through hole of smaller diameter and a through hole of larger diameter, the through hole of smaller being positioned at an upper portion of the through hole of larger diameter.

37. The alignment system according to claim 36, wherein the fixing insertion member is inserted in the fixing holder member, and locks and fixes the tray.

38. The alignment system according to claim 35, wherein the fixing insertion member is inserted in the fixing holder member, and locks and fixes the tray.

39. The alignment system according to claim 34, wherein the fixing insertion member is inserted in the fixing holder member, and locks and fixes the tray.

40. The alignment system according to claim 39, wherein a groove is formed at the fixing insertion member, and the groove of the fixing insertion member is inserted into and mounted in the fixing holder member.

41. The alignment system according to claim 38, wherein a groove is formed at the fixing insertion member, and the groove of the fixing insertion member is inserted into and mounted in the fixing holder member.

42. The alignment system according to claim 37, wherein a groove is formed at the fixing insertion member, and the groove of the fixing insertion member is inserted into and mounted in the fixing holder member.

43. The alignment system according to claim 36, wherein a groove is formed at the fixing insertion member, and the groove of the fixing insertion member is inserted into and mounted in the fixing holder member.

44. The alignment system according to claim 34, wherein at least one auxiliary attaching member is formed at the tray, and an auxiliary support member is formed at the alignment plate for engagement with said at least one auxiliary attaching member.

45. The alignment system according to claim 44, wherein said at least one auxiliary attaching member is conductive.

46. The alignment system according to claim 45, wherein said at least one auxiliary attaching member is made of magnetic material.

47. The alignment system according to claim 46, wherein said at least one auxiliary attaching member made of magnetic material includes one of at least one groove and at least one protrusion portion.

48. The alignment system according to claim 47, wherein the auxiliary support member is formed by magnetic material, and is supported and fixed in correspondence to said at least one auxiliary attaching member of the tray.

49. The alignment system according to claim 44, wherein a substrate frame is formed at the tray, receives the substrate, and is received in the tray.

50. The alignment system according to claim 49, wherein a substrate fixing member is formed at the substrate frame and receives the substrate.

51. The alignment system according to claim 50, wherein a frame fixing member is formed at the substrate frame to be received in the tray.

52. The alignment system according to claim 51, wherein a lower support portion for transportation is further formed at the tray.

53. The alignment system according to claim 51, wherein an upper support portion is formed at the tray and supplements transportation by the lower support portion.

54. The alignment system according to claim 34, wherein a substrate frame is formed at the tray, receives the substrate, and is received in the tray.

55. The alignment system according to claim 54, wherein a substrate fixing member is formed at the substrate frame and receives the substrate.

56. The alignment system according to claim 55, wherein a frame fixing member is formed at the substrate frame to be received in the tray.

57. The alignment system according to claim 56, wherein a lower support portion for transportation is further formed at the tray.

58. The alignment system according to claim 56, wherein an upper support portion is formed at the tray and supplements transportation by the lower support portion.

59. A vertical tray transporting assembly, comprising:
a plate tray for supporting a mask;
an upper support portion engaged with an upper side portion of the plate tray for supporting the plate tray;
a lower support portion engaged with a lower side portion of the plate tray for supporting the plate tray; and
a plate mask frame arranged between the plate tray and the mask for supporting the mask.

60. The vertical tray transporting assembly according to 59, wherein the plate mask frame is made of carbon fiber reinforced plastics (CFRP).

61. The vertical tray transporting assembly according to 60, wherein the plate tray is made of aluminum.

62. The vertical tray transporting assembly according to 59, wherein the upper support portion includes a guide groove, and the lower support portion has a bar shape.

63. The vertical tray transporting assembly according to 59, wherein the plate tray includes a through hole, the plate tray is engaged with a mask tray holder through the through hole, and an upper portion of the through hole is narrower than a lower portion of the through hole so that the plate tray is inserted in the through hole.

64. The vertical tray transporting assembly according to 59, wherein the plate tray further includes an attaching member arranged at a peripheral portion of the mask for improving adhesion force.

65. A deposition apparatus, comprising:
a process chamber;
a mask tray and a substrate tray vertically mounted in the process chamber and in parallel with each other, a mask and a substrate being mounted on the mask tray and the substrate tray, respectively;
a mask tray conveyer and a substrate tray conveyer for horizontally conveying the mask tray and the substrate tray, respectively, in parallel with each other;
a mask/substrate alignment plate for aligning and adhering the mask and the substrate conveyed by the mask tray conveyer and the substrate tray conveyer, respectively;
mask and substrate tray holders for supporting the mast tray and the substrate tray, respectively; and
a deposition source for injecting deposition materials into the substrate aligned and adhered to the mask;
wherein the mask tray includes a plate tray for supporting the mask, and a plate mask frame arranged between the plate tray and the mask for supporting the mask.

66. The deposition apparatus according to claim 65, wherein the mask frame is made of carbon fiber reinforced plastics (CFRP).

67. The deposition apparatus according to claim 65, wherein the plate tray is made of aluminum.

68. The deposition apparatus according to claim 65, wherein the substrate tray includes:
a plate tray for supporting the substrate; and
a substrate support member arranged between the plate tray and the substrate for supporting the substrate.

69. The deposition apparatus according to claim 68, wherein the substrate support member is made of carbon fiber reinforced plastics (CFRP).

70. The deposition apparatus according to claim 68, wherein the plate tray is made of aluminum.
